(19) United States
(12) Patent Application Publication
(10) Pub. No.: US 2026/0302722 A1
(43) Pub. Date: Oct. 1, 2026

(54) LIGHT SOURCE MODULE, OPTICAL ENGINE, IMAGE DISPLAY DEVICE, AND METHOD FOR MANUFACTURING LIGHT SOURCE MODULE

(71) Applicant: TDK Corporation, Tokyo (JP)

(72) Inventors: Takashi HONDA, Tokyo (JP); Taku SOMEYA, Tokyo (JP); Ryohei FUKUZAKI, Hong Kong (CN); Tsuyoshi KOMAKI, Tokyo (JP)

(73) Assignee: TDK Corporation, Tokyo (JP)

(21) Appl. No.: 19/568,072

(22) Filed: Mar. 16, 2026

(30) Foreign Application Priority Data
Mar. 26, 2025 (JP) 2025-051284

(51) Int. Cl. H01S 5/0237; H01S 5/02315; H01S 5/026; H01S 5/40

(52) U.S. Cl. CPC H01S 5/0237; H01S 5/02315; H01S 5/026; H01S 5/4093

(57) ABSTRACT

This light source module includes a plurality of subcarriers, a single optical waveguide substrate, and a metal laminated film for bonding a bonding surface of each of the plurality of subcarriers to a bonding surface of the optical waveguide substrate. Substrate-side metal films are composed of a plurality of isolated films, and dimensions of the isolated films in any two orthogonal directions are smaller than dimensions of carrier-side metal films in two orthogonal directions.

### BACKGROUND OF THE INVENTION

### Field of the Invention

The present disclosure relates to a light source module, an optical engine, an image display device, XR glasses, and a method for manufacturing a light source module.

The present application claims priority on Japanese Patent Application No. 2025-051284 filed on Mar. 26, 2025, the content of which is incorporated herein by reference.

### Description of Related Art

XR glasses such as augmented reality (AR) glasses and virtual reality (VR) glasses are expected to serve as compact wearable devices. In wearable devices such as AR glasses and VR glasses, miniaturization such that all functions fit within an ordinary eyeglass form factor is the key to widespread adoption.

Patent Document 1 discloses an integrated optical device (light source module) in which a base mount (subcarrier) holding an optical semiconductor element (for example, a laser diode), and a substrate (optical waveguide substrate) including an optical waveguide provided on a surface thereof are bonded with a metal layer therebetween in a state where a light emitting position of the optical semiconductor element and a position of the optical waveguide are accurately aligned, thereby achieving miniaturization.

In a configuration in which the base mount and the substrate are bonded with a metal layer therebetween (metal bonding), the bonding strength is improved as compared with a configuration bonded using an adhesive, and temperature dependence of the bonding strength is also curbed.

### PATENT DOCUMENT

### [Patent Document 1] Japanese Patent No. 7514094

### SUMMARY OF THE INVENTION

In a configuration in which a base mount (subcarrier) and a substrate (optical waveguide substrate) are integrated by metal bonding, heating by a method such as laser reflow during bonding may cause defects such as peeling or cracking at a bonded portion due to a difference in thermal expansion coefficient between a metal used for bonding (bonding metal) and the optical waveguide substrate. That is, during heating, the bonding metal expands significantly, whereas expansion of the optical waveguide substrate is small. Thereafter, as the temperature decreases, the bonding metal contracts significantly, whereas contraction of the optical waveguide substrate is small. Due to such a difference in volumetric expansion and contraction amounts, cracking or the like may occur at a bonded portion.

Particularly, when the optical waveguide substrate is made of a material having a low thermal conductivity, heat during bonding is likely to concentrate, and these problems are of concern. For example, since glass, fused silica, and the like have a low thermal conductivity and are brittle, defects such as cracking are of concern.

As a method for solving such problems, a method of moderating a rate of change of a heating temperature may be considered. In this method, the direction of heating is relatively easy to control, but cooling often proceeds in accordance with natural heat dissipation, making it difficult to control.

In addition, a method of lowering the bonding temperature may also be considered. However, for example, when Au-Sn eutectic joining is used, a formation temperature of an Au—Sn alloy is substantially determined by the material phase diagram, and thus there is a limit to lowering the bonding temperature.

The present disclosure has been made in consideration of the foregoing circumstances, and an object thereof is to provide a light source module having a configuration capable of curbing cracking during bonding heating, an optical engine, an image display device, XR glasses, and a method for manufacturing a light source module.

In order to solve the foregoing problems, the present disclosure provides the following features.

According to Aspect 1 of the present disclosure, there is provided a light source module including a plurality of laser elements; a plurality of subcarriers which each have a main surface and a bonding surface, on each of which one of the plurality of laser elements is mounted on the main surface, and which are arranged apart from each other in a first direction; a single optical waveguide substrate which has a main surface and a bonding surface, and on which optical waveguides for guiding laser light output from the plurality of laser elements are provided on the main surface side; and a metal laminated film in which a plurality of metal films for bonding the bonding surface of each of the plurality of subcarriers and the bonding surface of the optical waveguide substrate are laminated. Among the plurality of metal films constituting the metal laminated film, substrate-side metal films formed on the bonding surface of the optical waveguide substrate are composed of a plurality of isolated films arranged apart from each other at positions corresponding to the plurality of subcarriers. Dimensions of the isolated films in any two orthogonal directions are smaller than dimensions, in the two orthogonal directions, of carrier-side metal films formed on the bonding surfaces of the respective subcarriers.

According to Aspect 2 of the present disclosure, in the light source module according to Aspect 1, a metal material constituting the substrate-side metal films and a metal material constituting the carrier-side metal films are a combination of metal materials capable of eutectic bonding.

According to Aspect 3 of the present disclosure, in the light source module according to Aspect 2, the eutectic bonding is Au-Sn eutectic bonding.

According to Aspect 4 of the present disclosure, in the light source module according to any one of Aspects 1 to 3, the dimensions of the isolated films in the two orthogonal directions are equal to or smaller than three-quarters of the dimensions of the carrier-side metal films in the two orthogonal directions.

According to Aspect 5 of the present disclosure, in the light source module according to any one of Aspects 1 to 4, the isolated films include a plurality of partial films arranged apart from each other.

According to Aspect 6 of the present disclosure, in the light source module according to Aspect 5, the plurality of partial films are a plurality of vertically elongated partial films arranged in the first direction.

According to Aspect 7 of the present disclosure, in the light source module according to Aspect 6, the plurality of partial films are a plurality of checkerboard-pattern partial films arranged in a checkerboard pattern.

According to Aspect 8 of the present disclosure, in the light source module according to any one of Aspects 1 to 7, an anti-reflection film is formed in the vicinity of entrances of the optical waveguides on the bonding surface of the optical waveguide substrate, and the substrate-side metal films are formed so as to avoid the entrances of the optical waveguides.

According to Aspect 9 of the present disclosure, there is provided a light source module including a plurality of laser elements; a plurality of subcarriers which each have a main surface and a bonding surface, on each of which one of the plurality of laser elements is mounted on the main surface, and which are arranged apart from each other in a first direction; a single optical waveguide substrate which has a main surface and a bonding surface, and on which optical waveguides for guiding laser light output from the plurality of laser elements are provided on the main surface side; and a metal laminated film in which a plurality of metal films for bonding the bonding surface of each of the plurality of subcarriers and the bonding surface of the optical waveguide substrate are laminated. Among the plurality of metal films constituting the metal laminated film, substrate-side metal films formed on the bonding surface of the optical waveguide substrate include an Au film and a plurality of isolated films arranged apart from each other at positions corresponding to the plurality of subcarriers on the Au film. The Au film is arranged on the bonding surface of the optical waveguide substrate over at least a range covering all carrier-side metal films formed on the bonding surfaces of the respective subcarriers. The optical waveguide substrate is made of glass or fused silica.

According to Aspect 10 of the present disclosure, in the light source module according to Aspect 9, a thickness of the Au film is 0.1 μm or larger and smaller than 2 μm.

According to Aspect 11 of the present disclosure, in the light source module according to Aspect 9 or 10, dimensions of the isolated films in any two orthogonal directions are smaller than dimensions, in the two orthogonal directions, of the carrier-side metal films formed on the bonding surfaces of the respective subcarriers.

According to Aspect 12 of the present disclosure, in the light source module according to any one of Aspects 9 to 11, a metal material constituting the substrate-side metal films and a metal material constituting the carrier-side metal films are a combination of metal materials capable of eutectic bonding.

According to Aspect 13 of the present disclosure, in the light source module according to Aspect 12, the eutectic bonding is Au-Sn eutectic bonding.

According to Aspect 14 of the present disclosure, in the light source module according to any one of Aspects 9 to 13, the dimensions of the isolated films in the two orthogonal directions are equal to or smaller than three-quarters of the dimensions of the carrier-side metal films in the two orthogonal directions.

According to Aspect 15 of the present disclosure, in the light source module according to any one of Aspects 9 to 14, the isolated films include a plurality of partial films arranged apart from each other.

According to Aspect 16 of the present disclosure, in the light source module according to Aspect 15, the plurality of partial films are a plurality of vertically elongated partial films arranged in the first direction.

According to Aspect 17 of the present disclosure, in the light source module according to Aspect 15, the plurality of partial films are a plurality of checkerboard-pattern partial films arranged in a checkerboard pattern.

According to Aspect 18 of the present disclosure, in the light source module according to any one of Aspects 9 to 17, an anti-reflection film is formed in the vicinity of entrances of the optical waveguides on the bonding surface of the optical waveguide substrate, and the substrate-side metal films are formed so as to avoid the entrances of the optical waveguides.

According to Aspect 19 of the present disclosure, in the light source module according to any one of Aspects 1 to 18, all of the plurality of laser elements are visible-light laser elements outputting visible light.

According to Aspect 20 of the present disclosure, in the light source module according to Aspect 19, a plurality of the visible light rays are red light, green light, and blue light.

According to Aspect 21 of the present disclosure, there is provided an optical engine including the light source module according to Aspect 20, and an optical scanning mirror reflecting light output from the light source module while changing an angle so as to display an image.

According to Aspect 22 of the present disclosure, there is provided an image display device including the optical engine according to Aspect 21 mounted thereon.

According to Aspect 23 of the present disclosure, in the image display device according to Aspect 22, the image display device is XR glasses.

According to Aspect 24 of the present disclosure, there is provided a method for manufacturing the light source module according to any one of Aspects 1 to 8, 19, and 20. The method includes a step of forming, on the bonding surface of the optical waveguide substrate, substrate-side metal films composed of a plurality of isolated films arranged apart from each other at positions corresponding to a plurality of subcarriers; a step of forming, on the bonding surface of each of the plurality of subcarriers, carrier-side metal films having larger dimensions in any two orthogonal directions than the isolated films; and a step of bonding the optical waveguide substrate and the plurality of subcarriers while heating the substrate-side metal films and the carrier-side metal films.

According to Aspect 25 of the present disclosure, there is provided a method for manufacturing the light source module according to any one of Aspects 9 to 20. The method includes a step of forming, on the bonding surface of the optical waveguide substrate, an Au film having a thickness of 0.1 μm or larger and smaller than 2 μm over at least a range covering all carrier-side metal films formed on the bonding surfaces of the respective subcarriers; a step of forming, on the Au film, a plurality of isolated films arranged apart from each other at positions corresponding to the plurality of subcarriers to obtain substrate-side metal films; a step of forming, on the bonding surface of each of the plurality of subcarriers, carrier-side metal films corresponding to the isolated films; and a step of bonding the optical waveguide substrate and the plurality of subcarriers while heating the substrate-side metal films and the carrier-side metal films.

According to the light source module of the present disclosure, it is possible to provide a light source module having a configuration capable of curbing cracking during bonding heating.

### BRIEF DESCRIPTION OF THE DRAWINGS

FIG. 1 is a schematic plan view of a part of a light source module according to the present embodiment.

FIG. 2 is a schematic cross-sectional view taken along line A-A′ in the light source module shown in FIG. 1.

FIG. 3A is a schematic perspective view of subcarriers before bonding subcarriers and an optical waveguide substrate.

FIG. 3B is a schematic perspective view of an optical waveguide substrate before bonding the subcarriers and the optical waveguide substrate.

FIG. 4 is a schematic cross-sectional view taken along line B-B′ in the light source module shown in FIG. 1.

FIG. 5 is a schematic view showing a step of bonding the subcarriers and the optical waveguide substrate, in which the left diagram shows a state before bonding, and the right diagram shows a state after bonding.

FIG. 6A is a schematic front view showing a state where substrate-side metal films composed of a plurality of isolated films are formed on a bonding surface of the optical waveguide substrate.

FIG. 6B is a view showing a size relationship and a positional relationship between the isolated film and a carrier-side metal film by overlaying the carrier-side metal film corresponding to one isolated film among the plurality of isolated films shown in FIG. 6A.

FIG. 7A is a schematic plan view showing an example in which the isolated films of the substrate-side metal films include a plurality of partial films arranged apart from each other.

FIG. 7B is a schematic plan view showing another example in which the isolated films of the substrate-side metal films include a plurality of partial films arranged apart from each other.

FIG. 8A is a schematic plan view, as viewed in a Z direction, in the vicinity of the bonding surface of the optical waveguide substrate in an example of the light source module according to a second embodiment.

FIG. 8B is a schematic plan view, as viewed in the Z direction, in the vicinity of the bonding surface of the optical waveguide substrate in other example of the light source module according to the second embodiment.

FIG. 8C is a schematic plan view, as viewed in the Z direction, in the vicinity of the bonding surface of the optical waveguide substrate in other example of the light source module according to the second embodiment.

FIG. 8D is a schematic plan view, as viewed in the Z direction, in the vicinity of the bonding surface of the optical waveguide substrate in other example of the light source module according to the second embodiment.

FIG. 8E is a schematic plan view, as viewed in the Z direction, in the vicinity of the bonding surface of the optical waveguide substrate in other example of the light source module according to the second embodiment.

FIG. 8F is a schematic plan view, as viewed in the Z direction, in the vicinity of the bonding surface of the optical waveguide substrate in other example of the light source module according to the second embodiment.

FIG. 8G is a schematic plan view, as viewed in the Z direction, in the vicinity of the bonding surface of the optical waveguide substrate in other example of the light source module according to the second embodiment.

FIG. 9 is a schematic plan view of the light source module package accommodating the light source module of the present disclosure therein.

FIG. 10 is a view showing a cross section of the light source module arranged inside the light source module package shown in FIG. 9, partially cut along an X-Z plane.

FIG. 11 is a schematic plan view of a laser module accommodating the light source module which has the optical waveguide substrate including an optical waveguide layer composed of a lithium niobate film, in a state where a cover is removed.

FIG. 12 is a schematic plan view of the light source module shown in FIG. 11 as viewed from output surfaces of visible laser light and near-infrared laser light.

FIG. 13 is an explanatory conceptual view of XR glasses according to the present embodiment.

FIG. 14 is a conceptual view showing a state where an image is directly projected onto a retina by laser light output from the laser module according to the embodiment.

### DETAILED DESCRIPTION OF THE INVENTION

Hereinafter, an embodiment will be described in detail with reference to the drawings as appropriate. In the drawings used in the following description, in order to facilitate understanding of the characteristics, characteristic parts may be shown in an enlarged manner for convenience, and dimensional ratios or the like of each constituent element may differ from actual values. Materials, dimensions, and the like exemplified in the following description are merely examples. The present disclosure is not limited thereto and can be suitably modified and carried out within a range in which the effects of the present disclosure are exhibited.

### Light Source Module (First Embodiment)

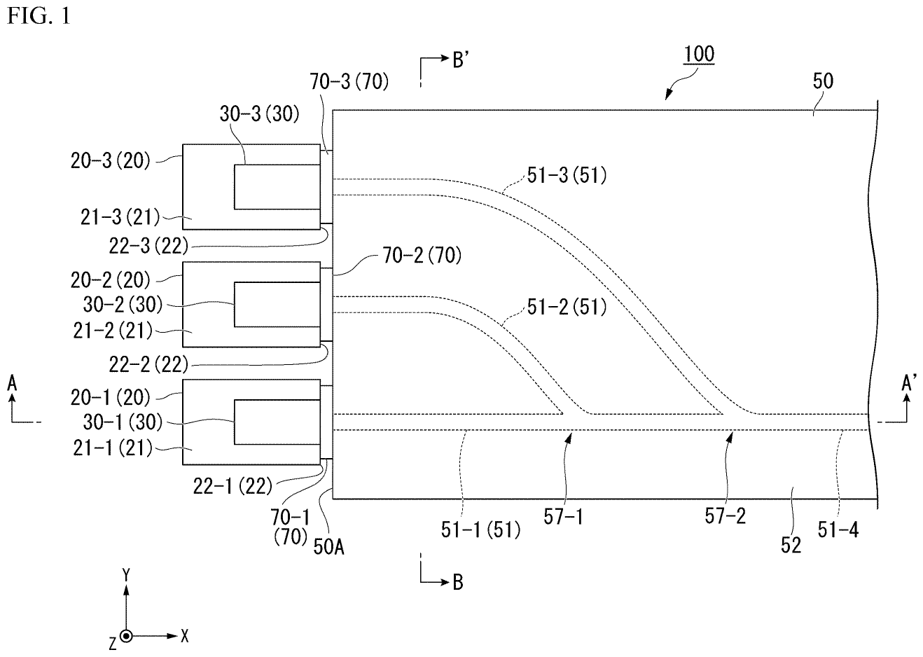

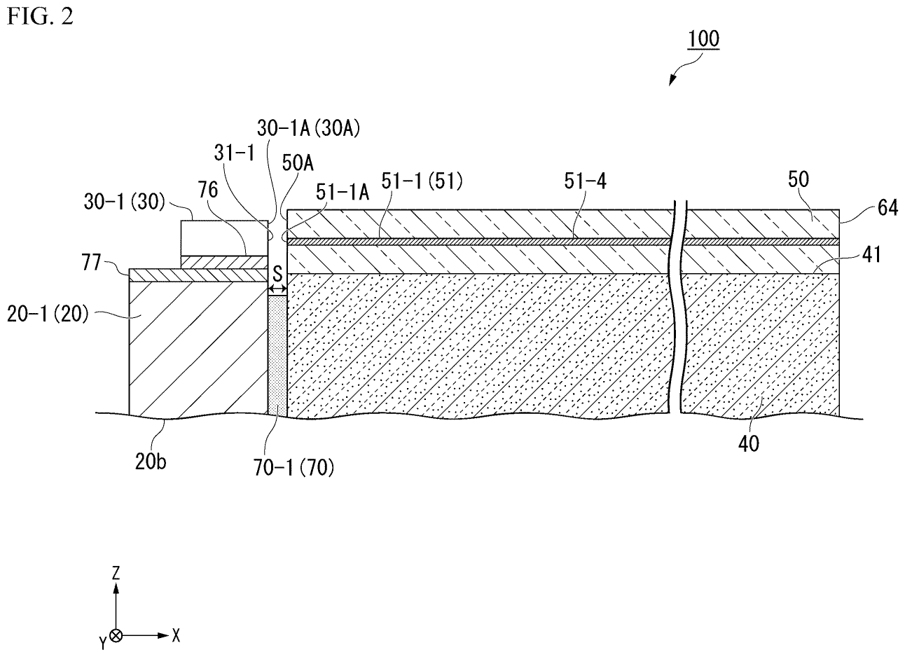

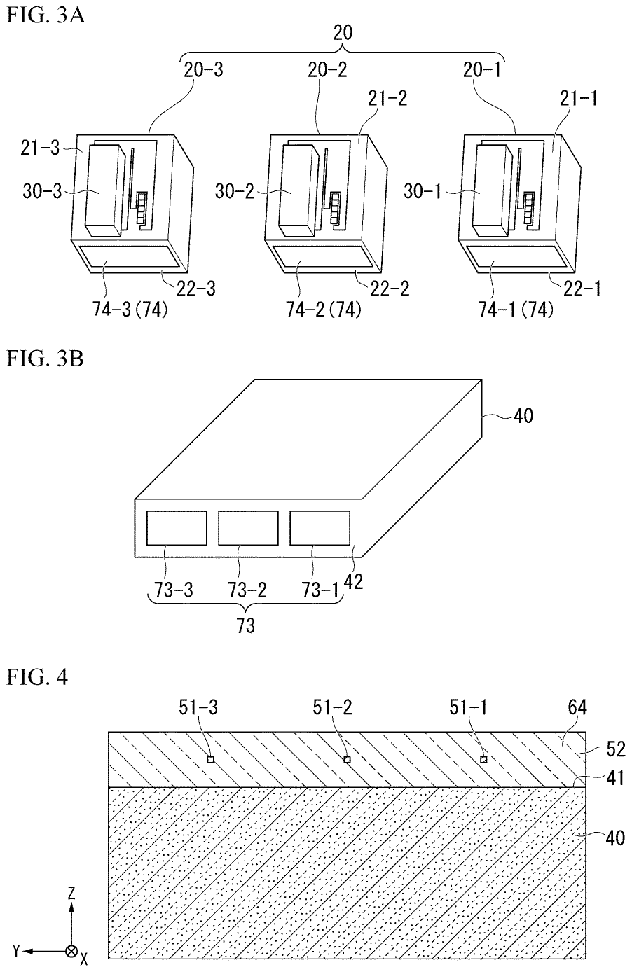

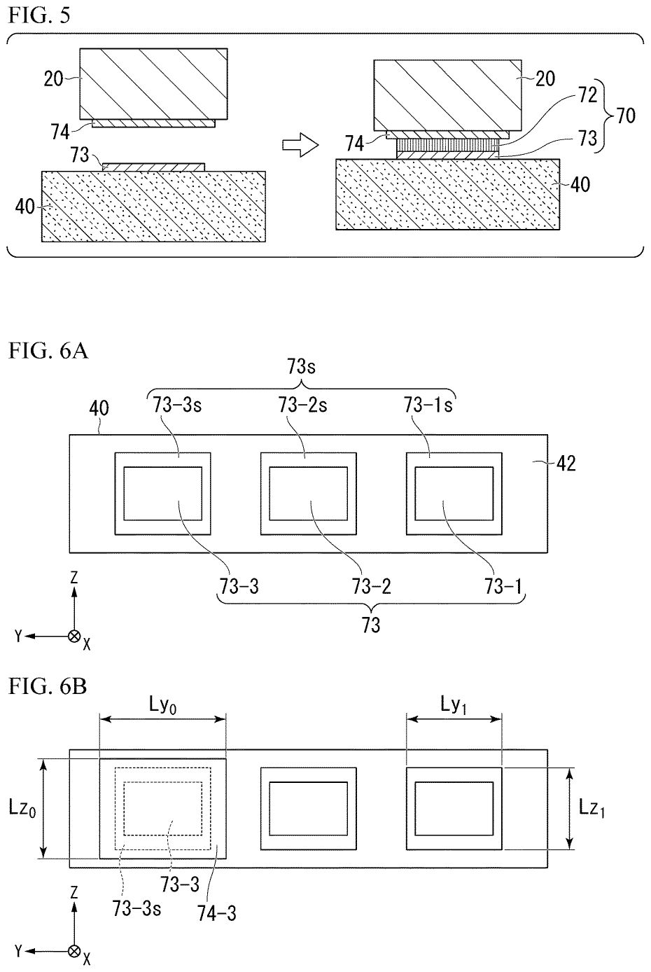

FIG. 1 is a schematic plan view of a part of a light source module of the present embodiment. FIG. 2 is a schematic cross-sectional view taken along line A-A′ in the light source module shown in FIG. 1. FIGS. 3A and 3B are schematic perspective views each showing subcarriers and an optical waveguide substrate before bonding. FIG. 3A is a schematic perspective view of the subcarriers, and FIG. 3B is a schematic perspective view of the optical waveguide substrate. In FIG. 3B, illustration of an optical waveguide layer 50 is omitted. FIG. 4 is a schematic cross-sectional view taken along line B-B′ in the light source module shown in FIG. 1. FIG. 5 is a schematic view showing a step of bonding the subcarriers and the optical waveguide substrate, in which the left diagram shows a state before bonding, and the right diagram shows a state after bonding. FIG. 6A is a schematic front view showing a state where substrate-side metal films composed of a plurality of isolated films are formed on a bonding surface of the optical waveguide substrate, and FIG. 6B is a view showing a size relationship and a positional relationship between the isolated films and carrier-side metal films by overlaying the carrier-side metal film corresponding to one isolated film among the plurality of isolated films shown in FIG. 6A when the subcarriers and the optical waveguide substrate are bonded.

In the drawings, an X direction is a direction in which the subcarriers and the optical waveguide substrate are bonded. A Y direction is a direction orthogonal to the X direction and is a direction in which a plurality of subcarriers are arranged. A Z direction is a direction orthogonal to a plane formed in the X direction and the Y direction.

A light source module 100 shown in FIG. 1 includes a plurality of laser elements 30 (30-1, 30-2, 30-3), a plurality of subcarriers 20 (20-1, 20-2, 20-3), a single optical waveguide substrate 40, and metal laminated films 70. The plurality of subcarriers 20 (20-1, 20-2, 20-3) respectively have main surfaces 21 (21-1, 21-2, 21-3) and bonding surfaces 22 (22-1, 22-2, 22-3), and the plurality of laser elements 30 (30-1, 30-2, 30-3) are mounted on the main surfaces 21 (21-1, 21-2, 21-3), respectively. The plurality of subcarriers 20 (20-1, 20-2, 20-3) are arranged apart from each other in the Y direction (first direction). The optical waveguide substrate 40 has a main surface 41 and a bonding surface 42, and optical waveguides 51 for guiding laser light output from the plurality of laser elements 30 (30-1, 30-2, 30-3) are provided on the main surface 41 side. A plurality of metal films are laminated in the metal laminated films 70, and the metal laminated films 70 bond the bonding surfaces 22 (22-1, 22-2, 22-3) of the plurality of respective subcarriers 20 (20-1, 20-2, 20-3) and the bonding surface 42 of the optical waveguide substrate 40. Among the plurality of metal films constituting the metal laminated films 70, metal films formed on the bonding surface 42 of the optical waveguide substrate 40 (which will hereinafter be referred to as “substrate-side metal films”) are composed of a plurality of isolated films arranged apart from each other at positions corresponding to the plurality of subcarriers 20 (20-1, 20-2, 20-3). Dimensions of the isolated films in any two orthogonal directions are smaller than dimensions, in two orthogonal directions, of metal films formed on the bonding surfaces of the respective subcarriers (which will hereinafter be referred to as “carrier-side metal films”).

### <Laser Element and Subcarrier>

Various laser elements can be used as the laser elements 30. For example, commercially available laser diodes (hereinafter sometimes referred to as “LDs”) emitting red light, green light, blue light, near-infrared light, ultraviolet light, and the like can be used. Light having a peak wavelength of 630 nm to 830 nm can be used as the red light (R), light having a peak wavelength of 500 nm to 550 nm can be used as the green light (G), and light having a peak wavelength of 380 nm to 500 nm can be used as the blue light (B). In addition, light having a peak wavelength of 830 nm to 2,000 nm can be used as the near-infrared light.

In the light source module 100 shown in FIG. 1, for convenience, the laser elements 30-1, 30-2, and 30-3 are described as an LD emitting red light, an LD emitting green light, and an LD emitting blue light, respectively. The laser elements 30-1, 30-2, and 30-3 can be respectively mounted on the individual subcarriers 20-1, 20-2, and 20-3 as bare chips (unpackaged chips), for example. The number of laser elements shown in FIG. 1 is three, but this is merely an example, and any number larger than one can be employed.

For example, the subcarriers 20-1, 20-2, and 20-3 consist of aluminum nitride (AlN), aluminum oxide (Al₂O₃), silicon (Si), or the like.

Metal films 77 and 76 are provided between the subcarriers 20 and the laser elements 30 (refer to FIG. 2). The subcarriers 20 and the laser elements 30 are connected with the metal films 77 and 76 therebetween. A known method can be utilized as a method for forming the metal films 77 and 76 without any particular limitations, and a known technique such as sputtering, vapor deposition, application of a metal paste, or the like can be utilized. For example, the metal films 77 and 76 may contain one or a plurality of metals selected from the group consisting of gold (Au), platinum (Pt), silver (Ag), lead (Pb), indium (In), nickel (Ni), titanium (Ti), tantalum (Ta), tungsten (W), an alloy of gold (Au) and tin (Sn), a tin (Sn)-silver (Ag)-copper (Cu)-based solder alloy (SAC), SnCu, InBi, SnPdAg, SnBiIn, and PbBiIn, or may consist of one or a plurality of metals selected from this group.

### <Optical Waveguide Layer and Optical Waveguide Substrate>

The optical waveguide layer 50 includes at least optical waveguides guiding laser light output from the laser elements. This optical waveguide layer is not particularly limited, and for example, a known configuration can be employed. Examples of the optical waveguide layer will be described below.

The optical waveguide layer 50 is a layer performing a function of a planar lightwave circuit (PLC). In addition, optical waveguides 51-1, 51-2, and 51-3 correspond to cores in optical fibers.

The optical waveguide layer 50 is formed on the optical waveguide substrate 40. In addition, as described above, the laser elements 30 are mounted on the subcarriers 20.

The optical waveguide substrate 40 and the subcarriers 20 are integrated by eutectic bonding. This eutectic bonding enables precise optical axis arrangement and realizes miniaturization.

For example, the optical waveguide substrate 40 consists of silicon (Si). The optical waveguide layer 50 is produced on the main surface 41 so as to be integrated with the optical waveguide substrate 40 by a semiconductor process including known photolithography and dry etching used when forming fine structures of integrated circuits and the like. As shown in FIG. 1, the optical waveguide layer 50 is provided with the same number of optical waveguides (cores) 51-1, 51-2, and 51-3 as the laser elements 30-1, 30-2, and 30-3, and a cladding 52 surrounding the optical waveguides 51-1, 51-2, and 51-3. The thickness of the cladding 52 and the dimensions of the optical waveguides 51-1, 51-2, and 51-3 in the width direction are not particularly limited. For example, the optical waveguides 51-1, 51-2, and 51-3 having width-direction dimensions of several micrometers are arranged in the cladding 52 having a thickness of approximately 50μm.

For example, the optical waveguides 51-1, 51-2, and 51-3 and the cladding 52 consist of a glass material (for example, quartz glass). In this case, the optical waveguide layer 50 may be referred to as a quartz-based PLC. The refractive indices of the optical waveguides 51-1, 51-2, and 51-3 are higher than the refractive index of the cladding 52 by a predetermined value. Accordingly, light input to each of the optical waveguides 51-1, 51-2, and 51-3 is propagated through each optical waveguide while being totally reflected at the interface between each optical waveguide and the cladding 52. For example, the optical waveguides 51-1, 51-2, and 51-3 are doped with impurities such as germanium (Ge) in an amount corresponding to the predetermined value described above. Alternatively, the cladding 52 may be made of a material having a different refractive index, such as SiN.

As shown in FIG. 1, the optical waveguides 51-1, 51-2, and 51-3 are gathered into one before reaching an output surface 64 of the optical waveguide layer 50. That is, the optical waveguides 51-1, 51-2, and 51-3 sequentially merge as they extend forward in the X direction and merge into a single optical waveguide 51-4. In order to prevent leakage light from the optical waveguides 51-1, 51-2, and 51-3, it is preferable that each of the optical waveguides 51-1, 51-2, and 51-3 be connected to the optical waveguide 51-4 with a radius of curvature equal to or greater than a predetermined radius of curvature.

By eutectic bonding between the optical waveguide substrate 40 and the subcarriers 20, each optical waveguide is arranged so as to face each corresponding laser element in a state where optical axes are accurately aligned such that the center of an input port of each of the optical waveguides 51-1, 51-2, and 51-3 of the optical waveguide layer 50 substantially coincides with the optical axis of output light from each of the corresponding laser elements 30-1, 30-2, and 30-3.

As shown in FIG. 2, an input surface 50A of the optical waveguide layer 50 is arranged so as to face an output surface 30A (30-1A) of the laser element 30. Specifically, an output port 31-1 of the laser element 30-1 faces an input port 51-1A of the waveguide 51-1. In the Y direction and the Z direction, the optical axis of red light emitted from the laser element 30-1 substantially overlaps the center of the input port 51-1A. Similarly, the output port of the laser element 30-2 faces the input port of the waveguide 51-2. In the Y direction and the Z direction, the optical axis of green light emitted from the laser element 30-2 substantially overlaps the center of the input port. The output port of the laser element 30-3 faces the input port of the waveguide 51-3. In the Y direction and the Z direction, the optical axis of blue light emitted from the laser element 30-3 substantially overlaps the center of the input port.

As shown in FIG. 1, red light, green light, and blue light emitted from the laser elements 30-1, 30-2, and 30-3 are respectively input to the optical waveguides 51-1, 51-2, and 51-3, and are then propagated through the respective optical waveguides. The red light and green light propagated through the optical waveguides 51-1 and 51-2 are coupled at a merging position 57-1. The coupled red and green light and the blue light propagated through the optical waveguide 51-3 are coupled at a merging position 57-2. The RGB light coupled at the merging position 57-2 is propagated through the optical waveguide 51-4, reaches the output surface 64, and is output from the output surface 64.

### <Bonded Portion Between Subcarrier and Optical Waveguide Substrate>

The plurality of individual subcarriers 20-1, 20-2, and 20-3 and the single optical waveguide substrate 40 are bonded with the metal laminated films 70 (70-1, 70-2, 70-3) therebetween.

As shown in FIG. 1, the metal laminated films 70 are composed of the metal laminated films 70-1, 70-2, and 70-3 arranged apart from each other.

The metal laminated films 70 (70-1, 70-2, 70-3) include first metal films 73 (73-1, 73-2, 73-3) serving as the substrate-side metal films, and second metal films 74 (74-1, 74-2, 74-3) serving as the carrier-side metal films. The metal laminated films 70-1, 70-2, and 70-3 are electrically and spatially separated from each other.

Before bonding, as shown in FIG. 3B, the first metal films 73 (73-1, 73-2, 73-3) are installed on the bonding surface 42 of the optical waveguide substrate 40 so as to be spaced apart from each other. In addition, as shown in FIG. 3A, the second metal films 74 (74-1, 74-2, 74-3) are arranged on the respective bonding surfaces 22-1, 22-2, and 22-3 of the plurality of subcarriers 20 (20-1, 20-2, 20-3).

### <Bonded Portion>

Parts in which the subcarriers and the optical waveguide substrate are bonded are referred to as bonded portions.

A step of bonding the subcarriers and the optical waveguide substrate will be described using FIG. 5. The left diagram shows a state before bonding, and the right diagram shows a state after bonding.

In bonding the subcarriers 20 and the optical waveguide substrate 40, as shown in the left diagram, the second metal films 74 (74-1, 74-2, 74-3) serving as the carrier-side metal films, and the first metal films 73 (73-1, 73-2, 73-3) serving as the substrate-side metal films, which will constitute the bonded portions, are formed in advance.

Next, the bonded portion is heated by a known method such as laser irradiation to melt the metal films, and one or both of the subcarriers and the optical waveguide substrate is pressed such that they are bonded by eutectic bonding. The first metal film 73 and the second metal film 74 are a combination of metals capable of eutectic bonding. The bonded portion after bonding includes the first metal film 73, a third metal film 72, and the second metal film 74. Since the bonded portions are formed by metal films which have once been melted and then solidified while forming a joint, it is difficult to accurately depict its form. However, in order to capture its features, the third metal film 72 is conceptually depicted as a eutectic metal between the first metal film 73 and the second metal film 74.

The metal laminated films 70 are not continuously formed films, but are separated films arranged apart from each other. Since the films are separated films, occurrence of capacitive coupling is curbed, and crosstalk is curbed.

Bonding is realized by eutectic bonding between the first metal films 73 and the second metal films 74.

A preferable example of eutectic joining is Au-Sn bonding. As materials of the first metal films 73 and the second metal films 74, a combination of forming Au-Sn bonding during bonding is preferable.

For example, when the first metal films 73 serving as the substrate-side metal films are made of an Sn-containing alloy such as Sn, Sn-Ag-Cu (SAC), or Sn-Ag-In, the second metal films 74 serving as the carrier-side metal films are preferably metals capable of being eutectic with Sn. For example, the second metal films 74 can contain one selected from the group consisting of Au, Si, Al, Ni, Pb, Zn, and Pt, or an alloy of these, and are more preferably made of Au or an alloy containing Au.

The materials of the first metal films 73 and the second metal films 74 may be combined in a reversed manner.

FIG. 6A is a schematic plan view of the bonding surface 42 of the optical waveguide substrate 40. The example in FIG. 6A shows a case where seed layers 73s (73-1s, 73-2s, 73-3s) are formed before forming the first metal films 73 (73-1, 73-2, 73-3). The seed layers 73s function as seeds for promoting growth of the first metal films 73 and also improve adhesion between the optical waveguide substrate 40 and the first metal films 73. In this case, since the seed layers 73s and the first metal films 73 fuse together through melting and solidification during bonding, the seed layers are regarded as parts of the first metal films (substrate-side metal films) after bonding. In FIG. 6A, for convenience, the dimensions of the seed layers 73-1s, 73-2s, and 73-3s are shown as being larger than the dimensions of the first metal films 73-1, 73-2, and 73-3. However, in actuality, the dimensions of each of the first metal films 73-1, 73-2, and 73-3 and each of the seed layers 73-1s, 73-2s, and 73-3s are the same, and positional relationships between each first metal film and each seed layer are the same.

FIG. 6B is a view showing a size relationship and a positional relationship between the isolated film and the carrier-side metal film by overlaying the carrier-side metal film 74-3 corresponding to one isolated film 73-3 among the three isolated films 73-1, 73-2, and 73-3 shown in FIG. 6A when the subcarriers and the optical waveguide substrate are bonded.

In FIG. 6B, Ly₀ and Lz₀ respectively indicate a length in the Y direction and a length in the Z direction of the carrier-side metal film 74-3. In addition, Ly₁ and Lz₁ respectively indicate a length in the Y direction and a length in the Z direction of the first metal film 73-3.

As shown in FIG. 6B, the isolated films (first metal films) are formed such that the lengths in the Y direction and the Z direction orthogonal to each other are smaller than the lengths of the carrier-side metal films in the Y direction and the Z direction.

The Y direction and the Z direction are an example of two orthogonal directions, and the isolated films (first metal films) are formed such that the lengths thereof in any two orthogonal directions are smaller than the lengths of the carrier-side metal films.

When the isolated film 73-3 is included (encompassed) in the carrier-side metal film 74-3, the lengths (dimensions) of the isolated film 73-3 in any two orthogonal directions are smaller than the lengths of the carrier-side metal films.

By constituting the first metal films (substrate-side metal films) as isolated films arranged apart from each other instead of continuous films, the volumetric expansion and contraction amounts can be reduced, and the difference in volumetric expansion and contraction amounts with respect to the optical waveguide substrate can be reduced.

The shapes and dimensions of the films may change due to bonding between the subcarriers and the optical waveguide substrate. However, the isolated films (first metal films) are formed to have a size with the lengths in any two orthogonal directions being smaller than the lengths of the carrier-side metal films after bonding.

In the light source module of the present disclosure (that is, after bonding), it is preferable that the dimensions of the isolated films (first metal films) in any two orthogonal directions are equal to or smaller than three-quarters of the dimensions of the carrier-side metal films in the two orthogonal directions.

Each of the isolated films 73-1, 73-2, and 73-3 of the substrate-side metal films may include a plurality of partial films arranged apart from each other. By constituting the isolated films to be further divided into finer parts, the volumetric expansion and contraction amounts of the isolated films can be further reduced.

In this case, each partial film may include a seed film.

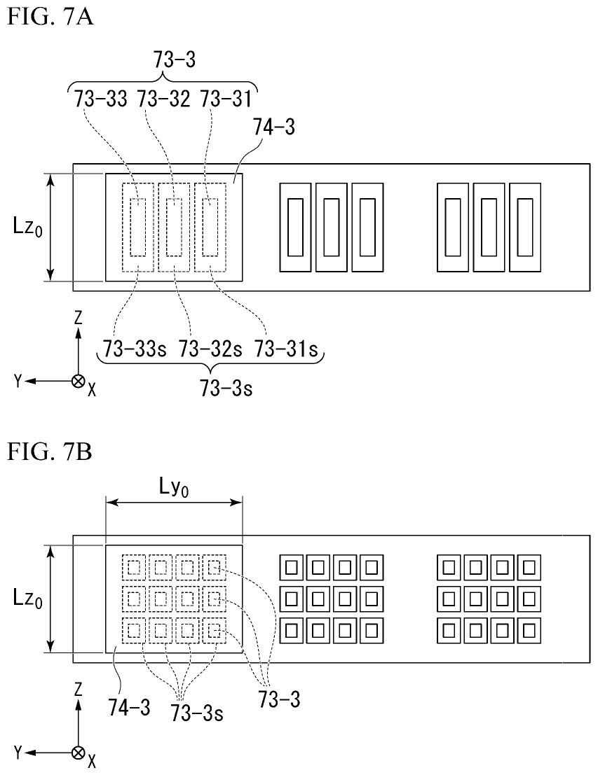

FIGS. 7A and 7B are schematic plan views showing an example in which the isolated films of the substrate-side metal films include a plurality of partial films arranged apart from each other. FIGS. 7A and 7B both show examples in which each partial film includes a seed film.

In FIG. 7A, the reference signs are provided only for one isolated film 73-3. In addition, in FIG. 7A, in order to indicate the size relationship and the positional relationship, the carrier-side metal film 74-3 corresponding to one isolated film 73-3 is also depicted.

The isolated film 73-3 shown in FIG. 7A includes three partial films 73-31, 73-32, and 73-33. Seed films 73-31s, 73-32s, and 73-33s are provided under the partial films 73-31, 73-32, and 73-33, respectively.

The number three is merely an example, and the number of partial films may be two, four, or more.

The partial films 73-31, 73-32, and 73-33 are vertically elongated partial films elongated in the Z direction, and are arranged side by side in the Y direction.

The isolated film 73-3 shown in FIG. 7B includes twelve (four in the Y direction and three in the Z direction) checkerboard-shaped partial films arranged in a checkerboard pattern (grid shape). The number twelve is merely an example, and the number may be eleven or smaller, or fourteen or larger. A seed film is provided under each checkerboard-shaped partial film.

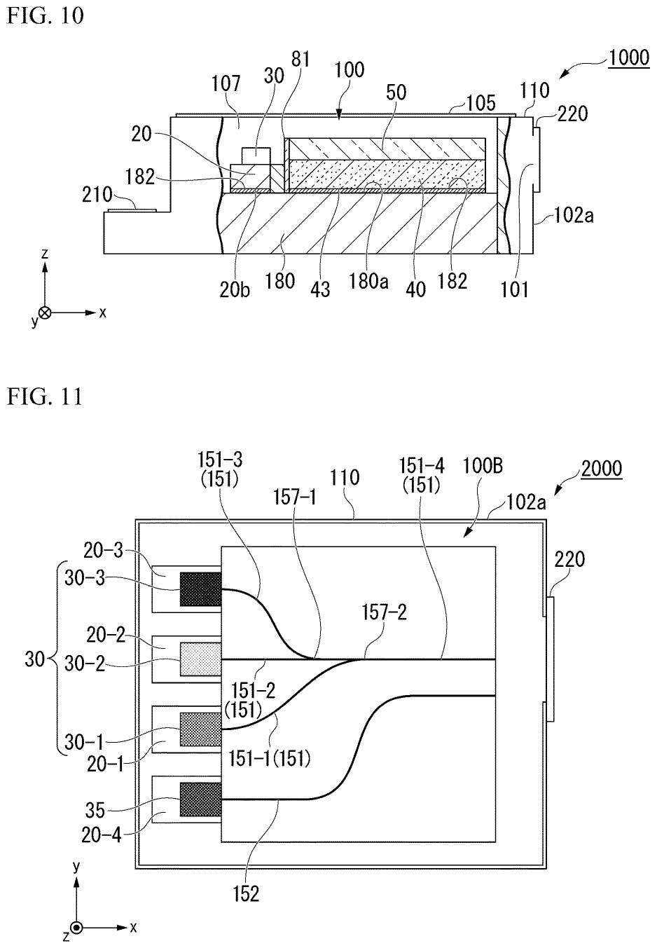

An anti-reflection film 81 (refer to FIG. 10) may be provided in a region including a part in the vicinity of entrances of the optical waveguides on the bonding surface 42 of the optical waveguide substrate 40.

In this configuration, the substrate-side metal films are formed so as to avoid the entrances of the optical waveguides.

The anti-reflection film 81 is a film for preventing input light to the input surface 50A of the optical waveguide layer 50 or output light from the output surface 64 of the optical waveguide layer 50 from being reflected in a direction opposite to the direction in which light enters each surface, and for enhancing the transmittance of input light or output light. For example, the anti-reflection film 81 is a multilayer film formed by alternately laminating a plurality of kinds of dielectrics with predetermined thicknesses corresponding to the wavelengths of red light, green light, and blue light (input light). Examples of the dielectrics include titanium oxide (TiO₂), tantalum oxide (Ta₂O₅), silicon oxide (SiO₂), and aluminum oxide (Al₂O₃).

### Light Source Module (Second Embodiment)

The light source module according to the second embodiment differs from the light source module according to the first embodiment in that Au films are provided on the bonding surface of the optical waveguide substrate over a range covering all the carrier-side metal films.

In the light source module according to the second embodiment, thin films made of Au which is a ductile material (Au films) are provided on the bonding surface of the optical waveguide substrate among the metal laminated films bonding the subcarriers and the optical waveguide substrate, and metal films contributing to eutectic joining are formed on the Au films. The Au films function as cushion layers for reducing stress applied to the optical waveguide substrate. That is, the Au films absorb an influence of volume change due to thermal expansion of the substrate-side metal films.

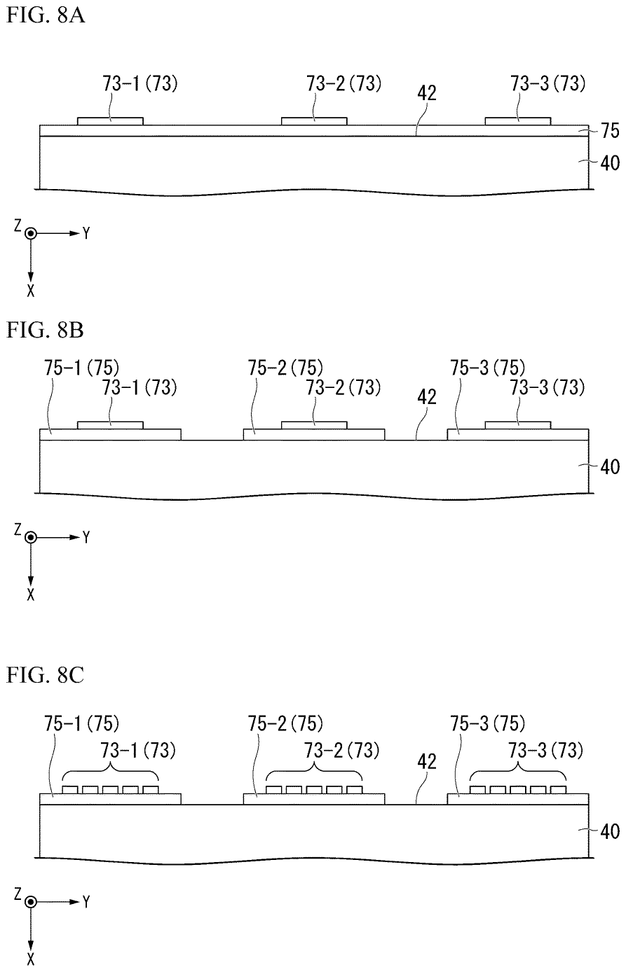

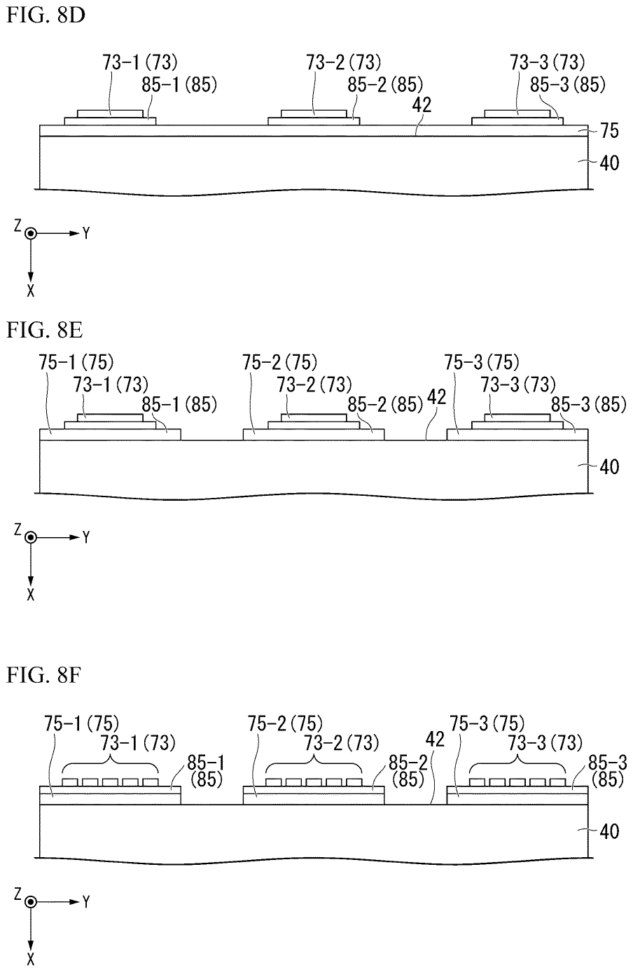

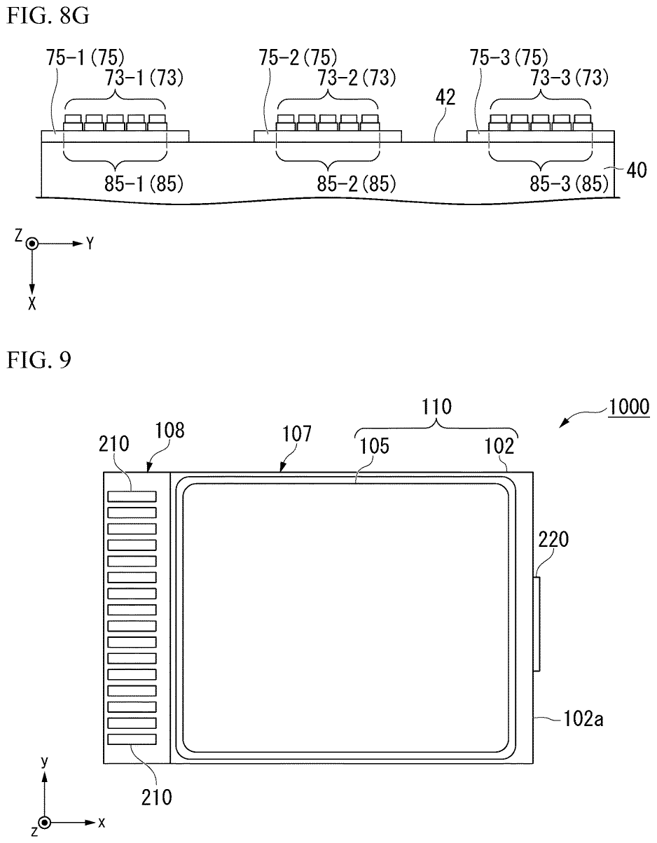

FIGS. 8A to 8C are schematic plan views, as viewed in the Z direction, in the vicinity of the bonding surface of the optical waveguide substrate in the light source module according to the second embodiment.

The same reference signs are applied to constituent elements common to those of the light source module according to the first embodiment, and the light source module according to the second embodiment will be described using the reference signs shown in the foregoing drawings and the reference signs shown in FIGS. 8A to 8G.

The light source module 100 according to the second embodiment includes the plurality of laser elements 30 (30-1, 30-2, 30-3), the plurality of subcarriers 20 (20-1, 20-2, 20-3), the single optical waveguide substrate 40, and the metal laminated films 70. The plurality of subcarriers 20 (20-1, 20-2, 20-3) respectively have the main surfaces 21 (21-1, 21-2, 21-3) and the bonding surfaces 22 (22-1, 22-2, 22-3), and the plurality of laser elements 30 (30-1, 30-2, 30-3) are mounted on the main surfaces 21 (21-1, 21-2, 21-3), respectively. The plurality of subcarriers 20 (20-1, 20-2, 20-3) are arranged apart from each other in the Y direction (first direction). The optical waveguide substrate 40 has the main surface 41 and the bonding surface 42, and the optical waveguides 51 for guiding laser light output from the plurality of laser elements 30 (30-1, 30-2, 30-3) are provided on the main surface 41 side. A plurality of metal films are laminated in the metal laminated films 70, and the metal laminated films 70 bond the bonding surfaces 22 (22-1, 22-2, 22-3) of the plurality of respective subcarriers 20 (20-1, 20-2, 20-3) and the bonding surface 42 of the optical waveguide substrate 40. Among the plurality of metal films constituting the metal laminated films 70, the metal films formed on the bonding surface 42 of the optical waveguide substrate 40 (which will hereinafter be referred to as “substrate-side metal films”) include Au films 75, and the plurality of isolated films 73 (73-1, 73-2, 73-3) arranged apart from each other at positions corresponding to the plurality of subcarriers 20 (20-1, 20-2, 20-3) on the Au films 75. The Au films 75 are arranged on the bonding surface 42 of the optical waveguide substrate 40 over at least a range covering all the metal films formed on the bonding surfaces 22 (22-1, 22-2, 22-3) of the respective subcarriers 20 (20-1, 20-2, 20-3) (which will hereinafter be referred to as “carrier-side metal films”).

As shown in FIGS. 8D to 8G, a configuration may be adopted in which other metal films 85 (85-1, 85-2, 85-3) are formed after the Au films 75 are formed and before the isolated films 73 are formed on the Au films 75, and the isolated films 73 are formed on the metal films 85 (85-1, 85-2, 85-3). When the metal films 85 are metal films made of Ni, Ta, or Ti, they function as barrier layers which effectively prevent diffusion of the materials of the Au films 75 and the isolated films 73.

In order for the Au films 75 to sufficiently exhibit their function as cushion layers, it is preferable that they have a thickness of 0.1 μm or larger and smaller than 2 μm.

The Au films 75 may be continuous films as shown in FIG. 8A, or may be discrete films arranged apart from each other for each subcarrier as shown in FIGS. 8B and 8C.

The first metal films 73 described above are formed on the Au films 75. As described above, the combination of materials of the first metal films 73 serving as the substrate-side metal films and the second metal films 74 serving as the carrier-side metal films may be a reversed combination of materials. Therefore, in this case, the first metal films 73 made of the material of the second metal films 74 described above are formed on the Au films 75. In this case, when the first metal films 73 are Au films, the Au films 75 and the first metal films 73 are not distinguished from each other.

When the substrate-side metal films of the metal laminated films 70 include the Au films 75, the optical waveguide substrate 40 is made of glass or fused silica.

The output surface 30A of the laser elements 30 and the input surface 50A of the optical waveguide layer 50 are arranged with a predetermined interval therebetween. The input surface 50A faces the output surface 30A, and there is a gap between the output surface 30A and the input surface 50A in the X direction. In consideration of the fact that the light source module 100 is used for XR glasses as well as the amount of light required for XR glasses, and the like, the size of the gap in the X direction is larger than 0 μm and equal to or smaller than 5 μm, for example.

### Light Source Module Package

FIG. 9 is a schematic plan view of a package accommodating the light source module of the present disclosure. FIG. 10 is a view showing a cross section of the light source module arranged inside the package shown in FIG. 9, partially cut along an X-Z plane.

In a light source module package 1000 shown in FIG. 10, the light source module 100 according to the foregoing embodiment is installed on an upper surface 180a of a base 180 and is accommodated inside a package 110.

In the light source module 100 accommodated in the package 110, it is preferable that bottom surfaces 20b of the subcarriers 20 and a bottom surface 43 of the optical waveguide substrate 40 be bonded so as to be positioned substantially on the same plane. Since the subcarriers 20 and the optical waveguide substrate 40 are bonded by metal eutectic bonding in the light source module 100, a positional deviation caused by a heating step is significantly curbed as compared with a configuration bonded by an adhesive.

Here, “substantially the same plane” allows a slight deviation between the bottom surfaces 20b of the subcarriers 20 and the bottom surface 43 of the optical waveguide substrate 40. Specifically, a deviation within a range of 20 μm or smaller with respect to the thickness of the optical waveguide substrate 40 in the Z direction is allowed, and the smaller the deviation, the better. The deviation is preferably 10 μm or smaller and is more preferably 5 μm or smaller.

When the bottom surfaces 20b of the subcarriers 20 and the bottom surface 43 of the optical waveguide substrate 40 are bonded so as to be positioned substantially on the same plane, heat generated by operation of the laser elements 30 can be efficiently dissipated from both the bottom surfaces 20b of the subcarriers 20 and the bottom surface 43 of the optical waveguide substrate 40.

In addition, when the bottom surfaces 20b of the subcarriers 20 and the bottom surface 43 of the optical waveguide substrate 40 are bonded so as to be positioned substantially on the same plane, both the bottom surfaces 20b of the subcarriers 20 and the bottom surface 43 of the optical waveguide substrate 40 can be bonded on one plane of the upper surface 180a of the base 180. Therefore, high bonding strength can be maintained, and the light source module 100 having excellent impact resistance can be realized.

In this manner, in the configuration in which the bottom surfaces 20b of the subcarriers 20 and the bottom surface 43 of the optical waveguide substrate 40 are bonded so as to be positioned substantially on the same plane, heat dissipation performance and impact resistance can be improved.

Inside the package 110, known constituent elements other than the light source module according to the foregoing embodiment may be provided. For example, a light receiver (photodetector: PD) can be accommodated.

When a PD is provided, variations in optical output of the laser element can be checked by observing the current flowing through the PD. In addition, a drive current of the laser element can be controlled such that the output becomes constant by monitoring the current flowing through the PD.

The package 110 includes a main body 102 having a cavity structure, and a cover 105 covering the main body 102.

The main body 102 includes a bottom portion on which members accommodated therein are mounted, and side wall portions 102a arranged so as to surround the members from lateral sides.

A light-transmitting window 101 allowing laser light L output from the laser elements 30 to be optically transmitted therethrough is formed in the side wall portion 102a arranged in a direction in which laser light is output.

Among the side wall portions of an accommodation portion 107, the light-transmitting window (opening) 101 is formed in the side wall portion 102a in the vicinity of the output portion of the laser light L output from the light source module package 1000. The opening 101 is formed substantially centered at a position intersecting the optical axis of laser light output at the side wall portion 102a. The opening 101 is covered by a glass plate 220 from outside the side wall portions 102a with no gap therebetween. That is, the accommodation portion 107 is hermetically sealed by the glass plate 220 in addition to the cover 105. Although the glass plate 220 is used for hermetic sealing, the material is not limited to a glass plate as long as laser light can be transmitted through. Anti-reflection films (not shown) may be provided on both plate surfaces of the glass plate 220.

An electrode portion 108 is arranged on the front side of the accommodation portion 107 in the X direction, that is, on a rearward side in the X direction. The upper surface of the electrode portion 108 is positioned below the upper surface of the accommodation portion 107. The bottom surface of the electrode portion 108 is positioned at substantially the same height as the bottom surface of the accommodation portion 107. A plurality of external electrode pads 210 are provided on the upper surface of the electrode portion 108 with an interval therebetween in the Y direction.

The bottom surfaces 20b of the subcarriers 20, and the bottom surface 43 of the optical waveguide substrate 40 need only be bonded to the upper surface 180a (one inner surface) of the base 180 with an adhesion layer 182 therebetween. In order to enhance thermal conductivity properties, a material obtained by mixing a filler into a resin is used for this adhesion layer 182. Examples of resins constituting the adhesion layer 182 include epoxy resin. In addition, copper powder, aluminum powder, alumina powder, or the like can be used as the filler for improving the thermal conductivity properties of the resin.

In order to maintain a certain level of thermal conductivity properties, the thermal conductivity of the adhesion layer 182 is preferably 0.5 W/m·K or higher, the thermal conductivity is more preferably 1 W/m·K or higher, and the thermal conductivity is still more preferably 4 W/m·K or higher.

In this manner, by bonding both the subcarriers 20 and the optical waveguide substrate 40 of the light source module to the upper surface 180a of the base 180 inside the package 110, heat generated by operation of the laser elements 30 can be efficiently dissipated toward the base 180 from both the bottom surfaces 20b of the subcarriers 20 and the bottom surface 43 of the optical waveguide substrate 40. Furthermore, by bonding both the bottom surfaces 20b of the subcarriers 20 and the bottom surface 43 of the optical waveguide substrate 40 using an adhesion layer made of a resin mixed with a filler, heat can be efficiently propagated toward the base 180 from both the bottom surfaces 20b of the subcarriers 20 and the bottom surface 43 of the optical waveguide substrate 40.

Next, a case where the optical waveguide layer provided in the light source module is made of a lithium niobate film (LiNbO₃) will be described. In contrast to the quartz-based PLC described above, such an optical waveguide layer in this case is sometimes referred to as an LN-based PLC.

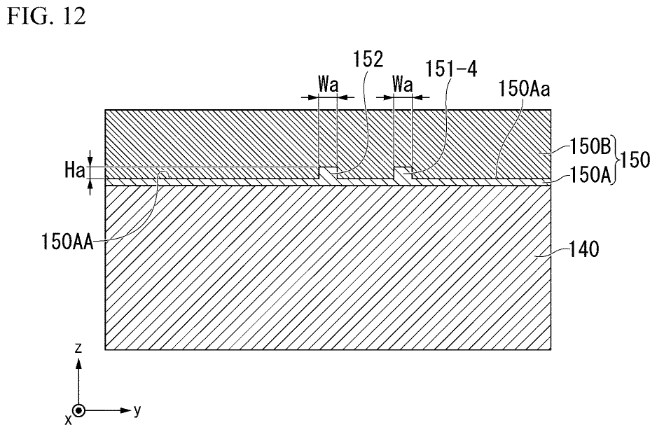

FIG. 11 shows a schematic plan view of a light source module package accommodating the light source module which includes the optical waveguide substrate including an optical waveguide layer composed of a lithium niobate film, in a state where the cover is removed. FIG. 12 is a schematic plan view of the light source module shown in FIG. 11 as viewed from output surfaces of the laser elements.

The same reference signs are applied to members common to those of the light source module and the light source module package described above, and description thereof may be omitted. FIG. 11 shows an example in which the light source module includes a near-infrared laser element in addition to RGB laser elements serving as the laser elements. Since a near-infrared laser is invisible, it can be used for eye tracking. The light source module described above may also be configured to include a near-infrared laser element.

In a light source module package 2000 shown in FIG. 11, the light source module 100 is accommodated in the package 110. The light source module 100 includes the laser elements 30 (30-1, 30-2, 30-3), the subcarriers 20 (20-1, 20-2, 20-3), the near-infrared laser element 35, a subcarrier 20-4, an optical waveguide substrate 140, and a bonded portion. The laser elements 30 (30-1, 30-2, 30-3) are respectively mounted on the subcarriers 20 (20-1, 20-2, 20-3). The near-infrared laser element 35 is mounted on the subcarrier 20-4. An LN-based PLC 150 is formed on a main surface of the optical waveguide substrate 140. The bonded portion is composed of a metal laminated film and bonds the bonding surfaces of the subcarriers 20 and the subcarrier 20-4 to the bonding surface of the optical waveguide substrate 140.

The near-infrared laser element 35 is mounted on the subcarrier 20-4 similarly to the laser elements 30, and the LN-based PLC 150 is formed on the optical waveguide substrate 140.

The light source module package 2000 includes the LN-based PLC 150 inside the package 110. The LN-based PLC 150 includes optical waveguides 151 (151-1, 151-2, 151-3) for guiding laser light output from the laser elements 30, and an optical waveguide 152 for guiding near-infrared laser light output from the near-infrared laser element 35.

In the light source module package 2000 as well, the optical waveguide substrate 140 is integrated with the subcarriers 20 and the subcarrier 20-4 by eutectic bonding.

This eutectic bonding enables precise optical axis arrangement and realizes miniaturization.

Examples of the optical waveguide substrate 140 include a sapphire substrate, an Si substrate, a thermally oxidized silicon substrate, and an artificial quartz substrate.

When the optical waveguides 151 and the optical waveguide 152 are formed of a lithium niobate (LiNbO₃) film, the substrate is not particularly limited as long as it has a refractive index lower than that of the lithium niobate film. However, a sapphire single-crystal substrate or a silicon single-crystal substrate is preferable as a substrate on which a single-crystal lithium niobate film can be formed as an epitaxial film. A crystal orientation of the single-crystal substrate is not particularly limited. For example, since a c-axis-oriented lithium niobate film has threefold symmetry, it is desirable that the single-crystal substrate (base) also have the same symmetry. Therefore, a c-plane substrate is preferable in the case of a sapphire single-crystal substrate, and a (111)-plane substrate is preferable in the case of a silicon single-crystal substrate.

In the light source module package 2000, the optical waveguide layer (LN-based PLC) 150 includes an optical waveguide film 150A including the optical waveguides 151 and the optical waveguide 152, and a waveguide cladding layer 150B formed on the optical waveguide film 150A so as to cover the optical waveguides 151 and the optical waveguide 152. The waveguide cladding layer 150B has a lower refractive index than the optical waveguide film 150A. For example, the waveguide cladding layer 150B is made of SiInO, SiO₂, Al₂O₃, MgF₂, La₂O₃, ZnO, HfO₂, MgO, Y₂O₃, CaF₂, In₂O₃, or a mixture thereof.

For example, the lithium niobate film (optical waveguide film 150A) is a c-axis-oriented lithium niobate film. For example, the lithium niobate film is an epitaxial film epitaxially grown on the optical waveguide substrate 140. An epitaxial film is a single-crystal film whose crystal orientation is aligned by a base substrate. The epitaxial film is a film having a single crystal orientation in the z direction and an in-plane xy direction, and the crystal is oriented with alignment in all of x-axis, y-axis, and z-axis directions. Whether the film formed on the optical waveguide substrate 140 is an epitaxial film can be proven by, for example, checking the peak intensity and the pole at the orientation position in 2θ-θ X-ray diffraction.

The composition of lithium niobate is LiₓNbA_{y}O_{z}. In the formula, A is an element other than Li, Nb, and O. In the formula, x is 0.5 to 1.2 and is preferably 0.9 to 1.05. In the formula, y is 0 to 0.5. In the formula, z is 1.5 to 4.0 and is preferably 2.5 to 3.5. For example, the element A is K, Na, Rb, Cs, Be, Mg, Ca, Sr, Ba, Ti, Zr, Hf, V, Cr, Mo, W, Fe, Co, Ni, Zn, Sc, or Ce, and two or more kinds of these elements may be combined.

The thickness of the lithium niobate film is 2 μm or smaller, for example. The thickness of the lithium niobate film refers to the thickness of a part other than a ridge portion. If the thickness of the lithium niobate film is large, crystallinity may deteriorate.

In addition, for example, the thickness of the lithium niobate film is approximately equal to or larger than 1/10 of the wavelength of light to be used. If the thickness of the lithium niobate film is small, confinement of light becomes weak, and light leaks into the optical waveguide substrate 140 or the waveguide cladding layer 150B.

The optical waveguides 151 and the optical waveguide 152 are optical paths in which light is propagated. The optical waveguides 151 and the optical waveguide 152 are ridges protruding from a first surface 150AA of a slab layer 150Aa of the optical waveguide film 150A. Hereinafter, the optical waveguide 151-1, the optical waveguide 151-2, the optical waveguide 151-3, and the optical waveguide 152 may be referred to as a ridge 151-1, a ridge 151-2, a ridge 151-3, and a ridge 152, respectively. The first surface 150AA is an upper surface of a part other than the ridge portion (slab layer 150Aa) of the optical waveguide film 150A. The optical waveguide film 150A consists of the ridges 151-1, 151-2, 151-3, and 152 and the slab layer 150Aa.

A ridge 151-4 and the ridge 152 shown in FIG. 12 have a rectangular cross-sectional shape, but any shape capable of guiding light may be adopted. For example, a trapezoidal shape, a triangular shape, or a semicircular shape may be adopted. A width Wa in the y direction is preferably 0.3 μm to 5.0 μm, and the height of the ridge (protrusion height Ha from the first surface 150AA) is preferably 0.1 μm to 1.0 μm, for example.

As shown in FIG. 11, the optical waveguide 151-1, the optical waveguide 151-2, and the optical waveguide 151-3 are gathered into one before reaching the output surface of the optical waveguide layer 150. That is, the optical waveguide 151-1, the optical waveguide 151-2, and the optical waveguide 151-3 sequentially merge as they extend forward in the x direction and merge into the single optical waveguide 151-4. In order to prevent leakage light from the optical waveguide 151-1, the optical waveguide 151-2, and the optical waveguide 151-3, it is preferable that each of the optical waveguide 151-1, the optical waveguide 151-2, and the optical waveguide 151-3 be connected to the optical waveguide 151-4 with a radius of curvature equal to or greater than a predetermined radius of curvature.

As shown in FIG. 11, red light, green light, and blue light emitted from the laser elements 30-1, 30-2 and 30-3 are respectively input on the ridges 151-1, 151-2, and 151-3 and are then propagated through the respective ridges. The blue light and the green light propagated through the ridges 151-3 and 151-2 are coupled at a predetermined merging position 157-1 behind a merging position 157-2 in the x direction. The coupled blue and green light and the red light propagated through the ridge 151-1 are coupled at the merging position 157-2. The RGB light coupled at the merging position 157-2 is propagated through the ridge 151-4, reaches the output surface, and is output from the output surface.

In addition, near-infrared light emitted from the laser element 35 is propagated through the ridge 152, reaches the output surface, and is output from the output surface.

Each of the optical waveguides 151-1, 151-2, 151-3, and 152 provided in the LN-based optical waveguide layer 150 may be a Mach-Zehnder-type optical waveguide. In this case, a known Mach-Zehnder-type optical modulation part, such as an electrode (not shown) for applying an electric field to the optical waveguide, is provided.

### Optical Engine and XR Glasses

In this specification, an optical engine is a device including a plurality of light sources, an optical system including a coupling portion coupling a plurality of light rays output from the plurality of light sources into a single light ray, an optical scanning mirror reflecting, while changing an angle thereof, light output from the optical system so as to display an image, and a control element controlling the optical scanning mirror.

The optical engine of the present disclosure includes the light source module according to the present disclosure, and an optical scanning mirror reflecting, while changing an angle thereof, light output from the light source module so as to display an image.

Hereinafter, an image display device including the optical engine of the present disclosure will be described as an example. XR glasses are an example of the image display device.

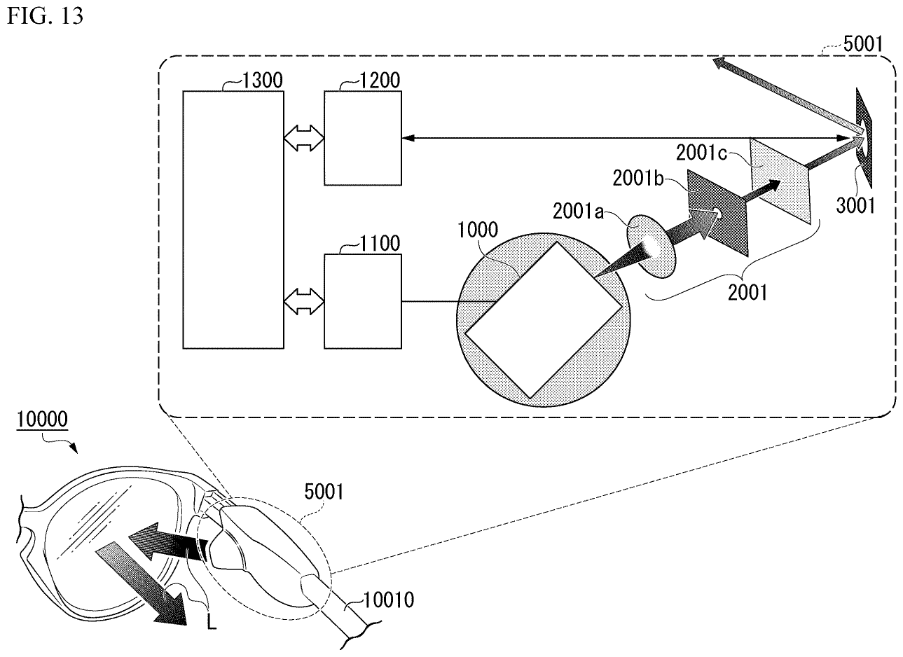

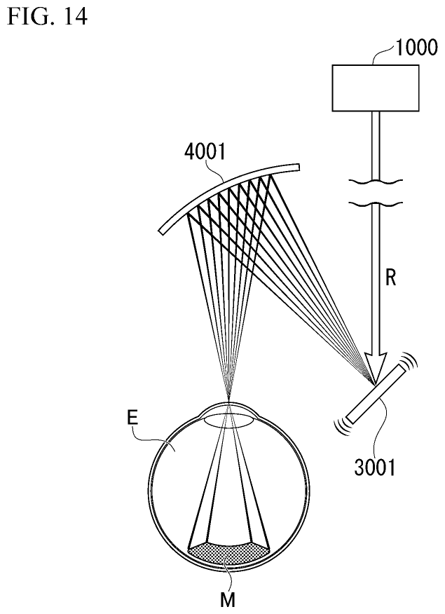

FIG. 13 is an explanatory conceptual view of an example of XR glasses of the present disclosure. FIG. 14 is a conceptual view showing a state where an image is directly projected onto a retina by laser light output from the light source module in the XR glasses shown in FIG. 13. The reference sign L indicates image display light.

XR glasses (eyeglasses) 10000 of the present disclosure are eyeglass-type terminals. “XR” is a collective term for virtual reality (VR), augmented reality (AR), and mixed reality (MR). The reference sign L shown in FIG. 10 indicates image display light.

In the XR glasses 10000 of the present disclosure shown in FIG. 13, the light source module package 1000 according to the present disclosure is mounted on an optical engine 5001 installed in a frame 1010. Instead of the light source module package 1000, the light source module package 2000 may be used.

As shown in FIG. 13, the optical engine 5001 includes the light source module package 1000, an optical scanning mirror 3001, an optical system 2001 connecting the light source module package 1000 and the optical scanning mirror 3001, a laser driver 1100, an optical scanning mirror driver 1200, and a video controller 1300 controlling these drivers.

For example, a MEMS mirror can be used as the optical scanning mirror 3001. In order to project a two-dimensional image, it is preferable to use, as the optical scanning mirror 3001, a two-axis MEMS mirror vibrating so as to reflect laser light while changing an angle thereof in a horizontal direction (X direction) and a vertical direction (Y direction).

The optical system 2001 performs optical processing of laser light output from the light source module package 1000. For example, the optical system 2001 including a collimator lens 2001a, a slit 2001b, and an ND filter 2001c can be used. The optical system 2001 shown in FIG. 13 is merely an example, and other configurations may be adopted.

As a light source in the light source module package 1000, for example, a light source having RGB laser elements including a red laser element 30-1, a green laser element 30-2, a blue laser element 30-3, and a near-infrared laser element 35 can be used.

In the XR glasses 10000 of the present disclosure shown in FIG. 13, as shown in FIG. 14, laser light R irradiated from the light source module package 1000 attached to the frame 1010 is reflected by the optical scanning mirror 3001, further reflected by a lens 4001 of the XR glasses 10000, enters a human eyeball E as the image display light L, and can directly project an image (video) onto a retina M.

By providing an eye-tracking mechanism, an image is directly projected onto the retina while performing eye tracking. A known eye-tracking mechanism can be used.

For example, the optical scanning mirror 3001 is a MEMS mirror. In order to project a two-dimensional image, it is preferable that the optical scanning mirror 3001 be a two-axis MEMS mirror which vibrates so as to reflect laser light while changing angles in a horizontal direction (X direction) and a vertical direction (Y direction).

Since the XR glasses 10000 of the present disclosure are mounted on the light source module package 1000 of the present disclosure, electric field efficiency is reduced.

### INDUSTRIAL APPLICABILITY

A light source module of the present disclosure is suitably applicable to optical engines, image display devices, and XR glasses.

### EXPLANATION OF REFERENCES

20 Subcarrier
30 Laser element
40, 140 Optical waveguide substrate
50, 150 Optical waveguide layer
100 Light source module
110 Package
1000, 2000 Light source module package
5001 Optical engine
10000 XR glasses

What is claimed is:

1. A light source module comprising:
a plurality of laser elements;
a plurality of subcarriers which each have a main surface and a bonding surface, on each of which one of the plurality of laser elements is mounted on the main surface, and which are arranged apart from each other in a first direction;
a single optical waveguide substrate which has a main surface and a bonding surface, and on which optical waveguides for guiding laser light output from the plurality of laser elements are provided on the main surface side; and
a metal laminated film in which a plurality of metal films for bonding the bonding surface of each of the plurality of subcarriers and the bonding surface of the optical waveguide substrate are laminated,
wherein among the plurality of metal films constituting the metal laminated film, substrate-side metal films formed on the bonding surface of the optical waveguide substrate are composed of a plurality of isolated films arranged apart from each other at positions corresponding to the plurality of subcarriers, and
dimensions of the isolated films in any two orthogonal directions are smaller than dimensions, in the two orthogonal directions, of carrier-side metal films formed on the bonding surfaces of the respective subcarriers.

2. The light source module according to claim 1,
wherein a metal material constituting the substrate-side metal films and a metal material constituting the carrier-side metal films are a combination of metal materials capable of eutectic bonding.

3. The light source module according to claim 2,
wherein the eutectic bonding is Au—Sn eutectic bonding.

4. The light source module according to claim 1,
wherein the dimensions of the isolated films in the two orthogonal directions are equal to or smaller than three-quarters of the dimensions of the carrier-side metal films in the two orthogonal directions.

5. The light source module according to claim 1,
wherein the isolated films include a plurality of partial films arranged apart from each other.

6. The light source module according to claim 5,
wherein the plurality of partial films are a plurality of vertically elongated partial films arranged in the first direction.

7. The light source module according to claim 6,
wherein the plurality of partial films are a plurality of checkerboard-pattern partial films arranged in a checkerboard pattern.

8. The light source module according to claim 1,
wherein an anti-reflection film is formed in the vicinity of entrances of the optical waveguides on the bonding surface of the optical waveguide substrate, and the substrate-side metal films are formed so as to avoid the entrances of the optical waveguides.

9. A light source module comprising:
a plurality of laser elements;
a plurality of subcarriers which each have a main surface and a bonding surface, on each of which one of the plurality of laser elements is mounted on the main surface, and which are arranged apart from each other in a first direction;
a single optical waveguide substrate which has a main surface and a bonding surface, and on which optical waveguides for guiding laser light output from the plurality of laser elements are provided on the main surface side; and
a metal laminated film in which a plurality of metal films for bonding the bonding surface of each of the plurality of subcarriers and the bonding surface of the optical waveguide substrate are laminated,
wherein among the plurality of metal films constituting the metal laminated film, substrate-side metal films formed on the bonding surface of the optical waveguide substrate include an Au film and a plurality of isolated films arranged apart from each other at positions corresponding to the plurality of subcarriers on the Au film,
the Au film is arranged on the bonding surface of the optical waveguide substrate over at least a range covering all carrier-side metal films formed on the bonding surfaces of the respective subcarriers, and
the optical waveguide substrate is made of glass or fused silica.

10. The light source module according to claim 9, wherein a thickness of the Au film is 0.1 μm or larger and smaller than 2 μm.

11. The light source module according to claim 9,
wherein dimensions of the isolated films in any two orthogonal directions are smaller than dimensions, in the two orthogonal directions, of the carrier-side metal films formed on the bonding surfaces of the respective subcarriers.

12. The light source module according to claim 9,
wherein a metal material constituting the substrate-side metal films and a metal material constituting the carrier-side metal films are a combination of metal materials capable of eutectic bonding.

13. The light source module according to claim 12, wherein the eutectic bonding is Au—Sn eutectic bonding.

14. The light source module according to claim 11,
wherein the dimensions of the isolated films in the two orthogonal directions are equal to or smaller than three-quarters of the dimensions of the carrier-side metal films in the two orthogonal directions.

15. The light source module according to claim 9,
wherein the isolated films include a plurality of partial films arranged apart from each other.

16. The light source module according to claim 15,
wherein the plurality of partial films are a plurality of vertically elongated partial films arranged in the first direction.

17. The light source module according to claim 15,
wherein the plurality of partial films are a plurality of checkerboard-pattern partial films arranged in a checkerboard pattern.

18. The light source module according to claim 9,
wherein an anti-reflection film is formed in the vicinity of entrances of the optical waveguides on the bonding surface of the optical waveguide substrate, and the substrate-side metal films are formed so as to avoid the entrances of the optical waveguides.

19. The light source module according to claim 1,
wherein all of the plurality of laser elements are visible-light laser elements outputting visible light.

20. The light source module according to claim 19,
wherein a plurality of the visible light rays are red light, green light, and blue light.

21. An optical engine comprising:
the light source module according to claim 20; and
an optical scanning mirror reflecting light output from the light source module while changing an angle so as to display an image.

22. An image display device comprising:
the optical engine according to claim 21 mounted thereon.

23. The image display device according to claim 22,
wherein the image display device is XR glasses.

24. A method for manufacturing the light source module according to claim 1, the method comprising:
a step of forming, on the bonding surface of the optical waveguide substrate, substrate-side metal films composed of a plurality of isolated films arranged apart from each other at positions corresponding to a plurality of subcarriers;
a step of forming, on the bonding surface of each of the plurality of subcarriers, carrier-side metal films having larger dimensions in any two orthogonal directions than the isolated films; and
a step of bonding the optical waveguide substrate and the plurality of subcarriers while heating the substrate-side metal films and the carrier-side metal films.

25. A method for manufacturing the light source module according to claim 9, the method comprising:
a step of forming, on the bonding surface of the optical waveguide substrate, an Au film having a thickness of 0.1 μm or larger and smaller than 2 μm over at least a range covering all carrier-side metal films formed on the bonding surfaces of the respective subcarriers;
a step of forming, on the Au film, a plurality of isolated films arranged apart from each other at positions corresponding to the plurality of subcarriers to obtain substrate-side metal films;
a step of forming, on the bonding surface of each of the plurality of subcarriers, carrier-side metal films corresponding to the isolated films; and
a step of bonding the optical waveguide substrate and the plurality of subcarriers while heating the substrate-side metal films and the carrier-side metal films.
